(19) United States
(12) Patent Application Publication
(10) Pub. No.: US 2009/0283129 A1
(43) Pub. Date: Nov. 19, 2009

(54) System and method for an array of intelligent inverters

(75) Inventor: Andrew Foss, San Jose, CA (US)

Correspondence Address: Munck Carter/NSC, P.O. Drawer 800889, Dallas, TX, 75380, US

(73) Assignee: National Semiconductor Corporation, Santa Clara, CA (US)

(21) Appl. No.: 12/454,244

(22) Filed: May 14, 2009

Related U.S. Application Data
(60) Provisional application No. 61/127,772, filed on May 14, 2008.

(51) Int. Cl. H01L 31/042

(52) U.S. Cl. 136/244

(57) ABSTRACT

A system and method for DC to AC conversion in a power generating array. The system and method includes a number of inverters coupled to a group of solar panels. A group controller coordinates operation of the inverters for interleaved switching of the inverters. The group controller communicates via a local area network, a wireless network, or both, to coordinate operation with additional groups of inverters coupled in parallel with additional solar panels.

### CROSS-REFERENCE TO RELATED APPLICATION(S) AND CLAIM OF PRIORITY

The present application is related to U.S. Provisional Patent No. 61/127,772, filed May 14, 2008, entitled “REDUNDANT ARRAY OF INTELLIGENT INVERTERS”. Provisional Patent No. 61/127,772 is assigned to the assignee of the present application and is hereby incorporated by reference into the present application as if fully set forth herein. The present application hereby claims priority under 35 U.S.C. §119(e) to U.S. Provisional Patent No. 61/127,772.

### TECHNICAL FIELD OF THE INVENTION

The present application relates generally to electrical power systems and, more specifically, to a system and method for converting energy from a solar-cell power array.

### BACKGROUND OF THE INVENTION

Photovoltaic (PV) panels (herein also referred to as “solar panels”) use radiant light from the sun to produce electrical energy. The solar panels include a number of PV cells to convert the sunlight into the electrical energy. The majority of solar panels use wafer-based crystalline silicon cells or a thin-film cell based on cadmium telluride or silicon. Crystalline silicon, which is commonly used in the wafer form in PV cells, is derived from silicon, a commonly used semi-conductor. PV cells are semiconductor devices that convert light directly into energy. When light shines on a PV cell, a voltage develops across the cell, and when connected to a load, a current flows through the cell. The voltage and current vary with several factors, including the physical size of the cell, the amount of light shining on the cell, the temperature of the cell, and external factors.

A solar panel (also referred to as PV module) is made of PV cells arranged in series and parallel. For example, the PV cells are first coupled in series within a group. Then, a number of the groups are coupled together in parallel. Likewise a PV array (also referred to as a “solar array”) is made of solar panels arranged in series and in parallel. Two or more PV arrays located in physical proximity to each other are referred to as a PV array site.

The electrical power generated by each solar panel is determined by the solar panel's voltage and current. In a solar array electrical connections are made in series to achieve a desired output string voltage and/or in parallel to provide a desired amount of string current source capability. In some cases, each panel voltage is boosted or bucked with a DC-DC converter.

The solar array is connected to an electrical load, an electrical grid or an electrical power storage device, such as, but not limited to, battery cells. The solar panels delivery Direct Current (DC) electrical power. When the electrical load, electrical grid or electrical power storage device operates using an Alternating Current (AC), (for example, sixty cycles per second or 60 Herz (Hz)), the solar array is connected to the electrical load, electrical grid, or electrical power storage device, through a DC-AC inverter.

Solar panels exhibit voltage and current characteristics described by their I-V curve. When the solar cells are not connected to a load, the voltage across their terminals is their open circuit voltage, V_{oc}. When the terminals are connected together to form a short circuit, a short circuit current, I_{sc}, is generated. In both cases, since power is given by voltage multiplied by current, no power is generated. A Maximum Power Point (MPP) defines a point wherein the solar panels are operating at a maximum power.

In a conventional solar array, all of the individual solar panels in the solar array must receive full sunlight for the array to work properly. If a portion of the array is shaded, or otherwise impaired, the entire array power output, even power output from those sections still exposed to sunlight, is lowered. Inevitably, efficiency reducing variations among panels also exist in many solar arrays. Therefore, a significant amount of energy is left unrealized when these variations go undetected and uncorrected.

Conventional attempts have been made to produce a “micro-inverter” that converts the DC power produced by a single solar panel into AC power. Per-panel (also referred to as per-module) inversion yields important advantages including localized Maximum Power Point Tracking (MPPT) tracking and the ability to replace obsolete solar panels with new ones over time. The replacement of obsolete solar panels can be perform without having to match voltage and current characteristics of the existing solar panels in the solar array, which are most probably obsolete.

However, in such conventional systems, existing solar panels operate at voltages below the peak voltage seen on the AC power grid, e.g., roughly 200v for 120v single-phase or 300v for 208v 3-phase. Because of this, such conventional systems must include a boost stage. The boost stage requires more complex circuitry, including a transformer that can be an expensive and unreliable component.

A trade-off exists in conventional inverter design. The tradeoff in the inverter design is related to the pulse wave modulation (“PWM”) switching frequency. Higher frequency increases the accuracy of the grid tracking and therefore reduces harmonic distortion. However, higher frequency equals more switching. The increased switching decreases efficiency due to switching losses.

Additionally, a tradeoff related to the physical size and inductance on board inductors exists in the inductor design. A large, high inductance inductor provides minimal harmonic distortion. However, large, high inductance inductors are expensive both in terms of monetary cost and physical space.

### SUMMARY OF THE INVENTION

A solar panel array for use in a solar cell power system is provided. The solar panel array includes a number of solar panels. The solar panel array also includes a plurality of inverters coupled in parallel to the solar panels. At least one group controller is configured to coordinate an operation of the plurality of inverters to perform an interleaved switching.

A converter for use in a solar cell power system is provided. The converter includes a first input terminal adapted to couple to a positive terminal of the number of solar panels. The converter also includes a first high side switch coupled to the first input terminal; a second high side switch coupled to the first input terminal; a first inductor coupled between the first high side switch and a first output terminal; a second inductor coupled between the second high side switch and a second output terminal; a first pull-down switch coupled to the first output; a second pull-down switch coupled to the second output; and a controller. The controller is configured to vary operation of the first and second high side switches and the first and second pull-down switches.

A method for current conversion for a photovoltaic array is provided. The method includes receiving electrical energy by a plurality of inverters from a plurality of solar panels. Switching of the inverters is coordinated to perform an interleaved conversion of a direct current energy to an alternating current energy by the plurality of inverters.

Before undertaking the DETAILED DESCRIPTION OF THE INVENTION below, it may be advantageous to set forth definitions of certain words and phrases used throughout this patent document. The term “packet” refers to any information-bearing communication signal, regardless of the format used for a particular communication signal. The terms “application,” “program,” and “routine” refer to one or more computer programs, sets of instructions, procedures, functions, objects, classes, instances, or related data adapted for implementation in a suitable computer language. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. The term “controller” means any device, system, or part thereof that controls at least one operation. A controller may be implemented in hardware, firmware, software, or some combination of at least two of the same. The functionality associated with any particular controller may be centralized or distributed, whether locally or remotely.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1A illustrates a schematic diagram of a solar array according to embodiments of the present disclosure;

FIG. 1B illustrates a schematic diagram of a solar panel according to embodiments of the present disclosure;

FIG. 1C illustrates example temperature data output line and pyranometer data line transmitting data via a network connection according to embodiments of the present disclosure;

FIG. 2 illustrates a schematic diagram of a solar array including intelligent inverters according to embodiments of the present disclosure;

FIG. 3 illustrates an intelligent inverter switching operation according to embodiments of the present disclosure;

FIG. 4 illustrates an example graph for power conversion efficiency vs. percent (%) rated output power for DC to AC inverters operating with two input voltages according to embodiments of the present disclosure;

FIG. 5 illustrates an example graph for adaptive power management according to embodiments of the present disclosure;

FIG. 6 illustrates a schematic diagram showing a solar panel including groups of power inverters coupled to the electrical power grid through a single AC switching means responsive to a central controller facility according to embodiments of the present disclosure;

FIG. 7A illustrates example graph of the waveforms of the current ripple produced according to embodiments of the present disclosure;

FIG. 7B illustrates an example graph of the current ripple of three synchronized inverters providing current to a load according to embodiments of the present disclosure;

FIG. 7C illustrates an example graph of the current for three coordinated interleaved inverters providing current to a load according to embodiments of the present disclosure;

FIG. 8 illustrates example graphs showing the effects of uncoordinated and coordinated interleaved inverters on harmonic distortion of output sine waves according to embodiments of the present disclosure;

FIG. 9 illustrates a schematic diagram for a transformer-less, no boost DC to AC power converter according to embodiments of the present disclosure; and

FIG. 10 illustrates is a schematic diagram for a solar array with inverter groups coupled in a three-phase delta configuration for 3-phase AC power generation according to embodiments of the present disclosure.

### DETAILED DESCRIPTION OF THE INVENTION

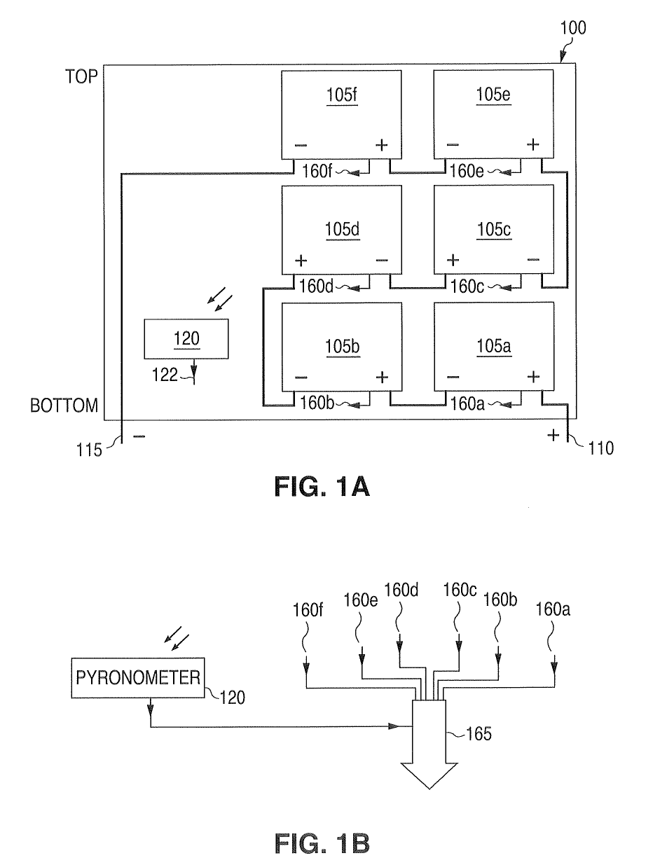

FIGS. 1A through 10, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged photovoltaic array system.

The scope of this disclosure is directed to an array of power inverters adapted to convert DC energy into AC energy. It will be understood that although the embodiments discussed herein below describe power inverters coupled to a solar energy generating device, such as one or more solar panels in a solar array, the power inverters can be coupled to, and receive DC energy from, any DC energy generating device such as, but not limited to, a wind generator or wind generation farm, a geothermal energy generating device, and a water (hydro) or wave generation device, or similar power sources.

FIG. 1A illustrates a schematic diagram of a solar array according to embodiments of the present disclosure. The embodiment of the solar array 100 shown in FIG. 1A is for illustration only. Other embodiments of the solar array could be used without departing from the scope of this disclosure.

A non-limiting example of how solar panels 105 are connected together to form the solar array 100 is shown in FIG. 1A. The solar array 100 includes six solar panels 105. It will be understood that illustration of six solar panels 105 is for example only and the solar array could include any number of solar panels 105. The solar panels 105 are coupled in series in three rows of two panels each, e.g., arranged from top to bottom. For example, the solar array 100 can be formed by a single series string. The solar panels 105 are coupled such that a negative terminal of a first solar panel 105a is coupled a positive terminal of a second solar panel 105b, a negative terminal of the second solar panel 105b is coupled a positive terminal of a third solar panel 105c, and so forth. Additionally, a positive terminal of the first solar panel 105a is coupled to a positive output terminal 110 of the solar array 100. In some embodiments, the positive terminal of the first solar panel 105a is the positive output terminal 110 of the solar array 100. Further, a negative terminal of the last solar panel 105f is coupled to a negative output terminal 115 of the solar array 100. In some embodiments, the negative terminal of the last solar panel 105f is the negative output terminal 115 of the solar array 100.

The solar array 100 includes a pyranometer 120, or solar radiation sensor. In some embodiments, the pyranometer is mounted independently in proximity to the solar array 100. In additional and alternative embodiments, the pyranometer is mounted on the solar array 100. The pyranometer 120 is a type of actinometer used to measure broadband solar irradiance on a planar surface. The pyranometer 120 is a sensor that is configured to measure the solar radiation flux density (in watts per meter square) from a field of view of one hundred eighty degrees Fahrenheit (180° F.). The pyranometer 120 is coupled to a data line 122 for transmitting data corresponding to the measured broadband solar irradiance at the solar array 100. The data output of pyranometer 120 is proportional to the amount of sunlight shining on the solar array 100.

FIG. 1B illustrates a schematic diagram of a solar panel 105 according to embodiments of the present disclosure. The embodiment of the solar panel 105 shown in FIG. 1B is for illustration only. Other embodiments of the solar panel 105 could be used without departing from the scope of this disclosure.

In some embodiments, strings of PV cells 125 within one or more solar panel 105 are coupled in parallel. For example, a first string 130 of PV cells 125 is coupled in parallel with a second string 140 of PV cells 125, and so forth, in the solar panel 105. It will be understood that illustration of two strings 130, 135 is for example purposes only and the solar panel 105 could include any number of strings.

Each string 130, 135 includes a number of PV cells 125 coupled in series such that a negative terminal of a first PV cell 125 is coupled to a positive terminal of a second PV cell 125 and so forth. Further, each string 130, 135 includes a bypass diode 140. In each string 130, 135, the bypass diode 140 is coupled between a positive terminal of the first PV cell 125 and the positive terminal 145 of the solar panel 105. A negative terminal 150 of the solar panel 105 is coupled to a negative terminal of the last PV cell 125 in each string 130, 135.

The bypass diode 140 assists with short circuit protection for the solar panel 105. Photovoltaic cells 125 are specially constructed P-N junctions and are subject to shorting-out when operating in hot weather under high current flow. In the event that a PV cell 125 in a string 130, 135 shorts-out, the voltage of the string 130, 135 with the shorted PV cell 125 would drop below the voltage of the other strings 130, 135. For example if a PV cell 125 in the first string 130 shorts-out, then the voltage of the first string 130 would drop more than one diode voltage drop below the voltage of the second string 135. Therefore, the bypass diode 140 would be reversed biased and would stop conducting so that the string 135 with the shorted PV cell 125 does not become a short circuit for the entire solar panel 105.

The solar panel 105 includes a temperature sensor 155. In some embodiments, the temperature sensor 155 is mounted on the solar panel 105. The temperature sensor 155 is configured to monitor the temperature at or on the solar panel 105. The temperature sensor 155 is coupled to a data output line 160. Each solar panel 105 includes a corresponding temperature data output line 160. For example, as illustrated in FIG. 1A, solar panel 105a includes temperature data output line 160a; solar panel 105b includes temperature data output line 160b; solar panel 105c includes temperature data output line 160c; solar panel 105d includes temperature data output line 160d; solar panel 105e includes temperature data output line 160e; and solar panel 105f includes temperature data output line 160f.

FIG. 1C illustrates example temperature data output line and pyranometer data line transmitting data via a network connection according to embodiments of the present disclosure. The embodiment temperature sensors and pyranometer transmitting data via a network connection shown in FIG. 1C is for illustration only. Other embodiments could be used without departing from the scope of this disclosure.

The temperature output data lines 160a-160f, e.g., the temperature output data lines 160 for a solar array 100, are coupled to a solar site manager via a network connection 165. Additionally, the data line 122 from the pyranometer 120 also is coupled to the site manager via the network connection 165. The network connection can be a Local Area Network (LAN) connection, a Wide Area Network (WAN) connection, a wireline connection, a wireless connection, or a combination of these.

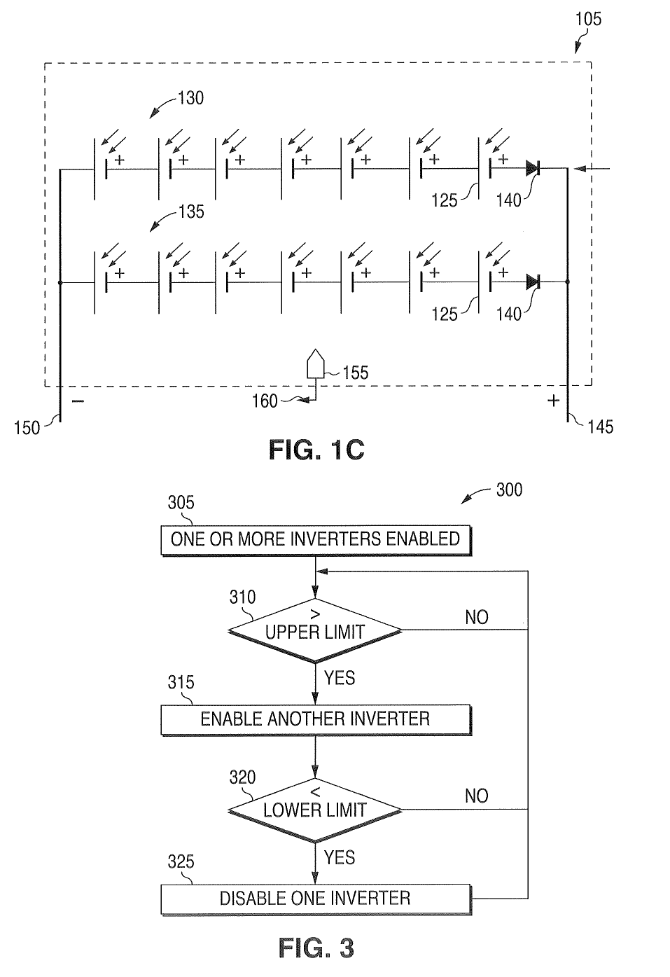

FIG. 2 illustrates a schematic diagram of a solar array including intelligent inverters according to embodiments of the present disclosure. The embodiment of the solar array 200 shown in FIG. 2 is for illustration only. Other embodiments could be used without departing from the scope of this disclosure.

The solar site includes a number of solar panels 205. The solar panels 205 can be of the same structure and configuration as the solar panels 105 described herein above. The solar panels 205 are coupled in series such that a negative terminal of the first solar panel 205a is coupled to a positive terminal of the second solar panel 205b; a negative terminal of the second solar panel 205b is coupled to a positive terminal of the third solar panel 205c; and a negative terminal of the third solar panel 205c is coupled to a positive terminal of the fourth solar panel 205d. It will be understood that illustration of four solar panels 205 is for example purposes only and the solar array 200 could include any number of solar panels 205.

A negative terminal of the last solar panel 205d is coupled to a negative (−) DC power line 210. A positive terminal of the first solar panel 205a is coupled to a positive (+) DC power line 215.

A number of power inverters 220 are coupled to the DC power lines 210, 215. For example, each power inverter 220 is coupled on its negative DC negative power input (−) 222 to the negative DC power line 210 and on its positive DC power input (+) 224 to the positive DC power line 215.

Each of the individual power inverters 220 includes multiple output lines A, B and C corresponding to respective AC sine waves. The AC electrical system operates in three phases of sine waves. The sine wave voltage is measured with respect to ground and, thus, has positive peaks and negative peaks. The three phases are denoted by “A”, “B” and “C” respectively. Each phase is separated from the next phase by one-hundred twenty degrees (120°). Therefore, the positive and negative peaks for each phase A, B, C have different phasing relative to the AC voltages on the other phases. The power inverters 220 are coupled to each other via the output lines A, B, C such each phase is tied to a corresponding phase (e.g., that have identical peak voltage timing or identical phasing). For example, output line A of the first inverter 220a is coupled to output line A of each of the second and third inverters 220b and 220c; output line B of the first inverter 220a is coupled to output line B of each of the second and third inverters 220b and 220c; and output line C of the first inverter 220a is coupled to output line C of each of the second and third inverters 220b and 220c. Each identically phased inverter 220 output line is coupled to one of a number of AC output lines 230, 232, 234. For example, output line A from each of the inverters 220 is coupled to AC output line 230; output line B from each of the inverters 220 is coupled to AC output line 232; and output line C from each of the inverters 220 is coupled to AC output line 234.

The power inverter 220 includes an internal AC switching device 240. The switching device 240 is responsive to control signals that are generated internally by the inverter 220. The switching device 240 couples individual power inverter outputs A, B, C to output lines 230, 232, 234 when an output power of the solar array 200 is above a certain (e.g., specified) threshold and is stable. The switching device 240 is configured to disconnect (e.g., sever the coupling of) the inverter 220 from output lines 230, 232, 234 in response to a disconnection event. A disconnection event can include, but is not limited to, the inverter 220 overheating, a failure of the inverter 220, and a disconnect command transmitted to the inverter 220 via the network 245 from the group controller 250. The network 245 can be a LAN connection or a WAN connection established via a wireline or a wireless communication medium.

Each inverter 220 is coupled to the network 245 via the data connection 255. In some embodiments, the data connection 255 is a multi-wire digital data line connection. The network 245 along with internal line drivers (not specifically illustrated) in power inverters 220 and in group controller 250 enable a bi-directional (e.g., two way) flow of digital data using a protocols well known in the art, such as RS-485.

The group controller 250 includes one or more processors and memory devices configured to receive and store output voltage data and current data from each inverter 220. The group controller 250 receives the output voltage data and current data from the inverters 220 in the inverter group by way of network 245. The group controller 250 is adapted to use the received output voltage data and current data in order to maintain the output power of the inverters 220 in the inverter group within an optimum power band or minimum conversion loss range of the output power.

One or more temperature and/or voltage sensors 270 included in each solar panel 205 and one or more radiation meters (e.g., pyranometers not specifically illustrated) transmit data through network 245 to the group controller 250. The group controller 250 sends commands to power inverters 220, via network 245, to change output current in order to maintain conversion of solar energy to electrical power at the MPP. Additionally and alternatively, the group controller 250 can send data collected from the solar panels 205 and power inverters 220 via a wireless data network to a central facility (not illustrated) using wireless data transmitter/receiver 260 and antenna 265. In some embodiments, the group controller 250 sends data to the central facility via a wireline data network using a wireline interface (not illustrated) such as, but not limited to, a communication port or modem. The group controller 250 is responsive to commands received from the central facility through antenna 265 and transmitter/receiver 260. The commands receive can include, but are not limited to, an inverter group shut down command that would be needed for inspection and maintenance of one or more elements in the solar array 200.

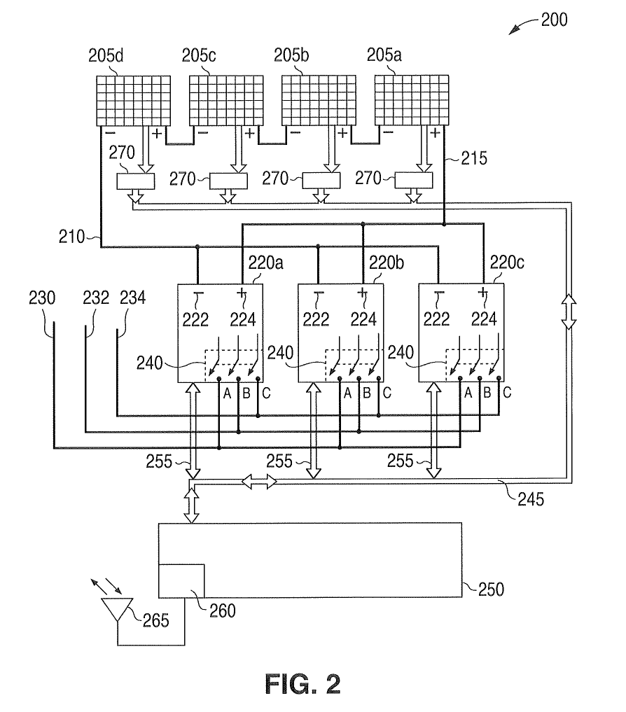

FIG. 3 illustrates an intelligent inverter switching operation according to embodiments of the present disclosure. The embodiment of the operation 300 shown in FIG. 3 is for illustration only. Other embodiments could be used without departing from the scope of this disclosure.

One or more of the inverters are enabled in step 305. Therefore, the inverters that are enabled output power to an AC electric load such as, but not limited to, an electric distribution grid.

In step 310, the output power of the inverter is measured against an upper power limit of the optimum power band for the inverter. The power can be measured individually by the inverter, measured by the group controller using data received from the inverter, or both. If the output power does not exceed the upper limit of the optimum power band for the inverter, the process repeats step 310 wherein the output power is measured continually or at specified intervals.

In the event that the output power of the operating inverter goes above an upper power limit of the optimum power band for one inverter, then a second (e.g., another) inverter in the group is enabled in step 315. An additional inverter (e.g., a second inverter if one inverter previously was enabled, a third inverter if two inverters previously were enabled, and so forth) is enabled such that the total output power is shared among the inverters. For example, if a second inverter is enabled, the two operating inverters will then share fifty percent (50%) of the total output power that was previously the upper power limit of the optimum power band for one inverter. Therefore, the two operating inverters operate within the optimum power band, but near the lower power limit of the optimum power band.

In an additional example, if two inverters in the group previously were enabled and output power of the two operating inverters goes above the upper power limit of the optimum power band for two inverters in step 310, then the third inverter in the group is enabled such that the three operating inverters will then share a third (e.g., 33.3%) of the power that was the upper power limit of the optimum power band for two inverters. Thus, the three operating inverters operate within the optimum power band.

In the event that more than one power inverter is enabled, the group controller measures the output power of the inverter and compares the measured value against a lower power limit of the optimum power band in step 320. The power can be measured individually by each inverter, measured by the group controller using data received from the inverters, or both. If the output power exceeds the lower limit of the optimum power band, the process returns to step 310 wherein the output power is measured continually or at specified intervals.

In the event that the output power of the group goes below the lower power limit of the optimum power band, one of the inverters is disabled in step 325 in order to bring output power of each inverter that remains in operation back within the optimum power band. Thereafter, the process returns to step 310 wherein the output power is measured continually or at specified intervals.

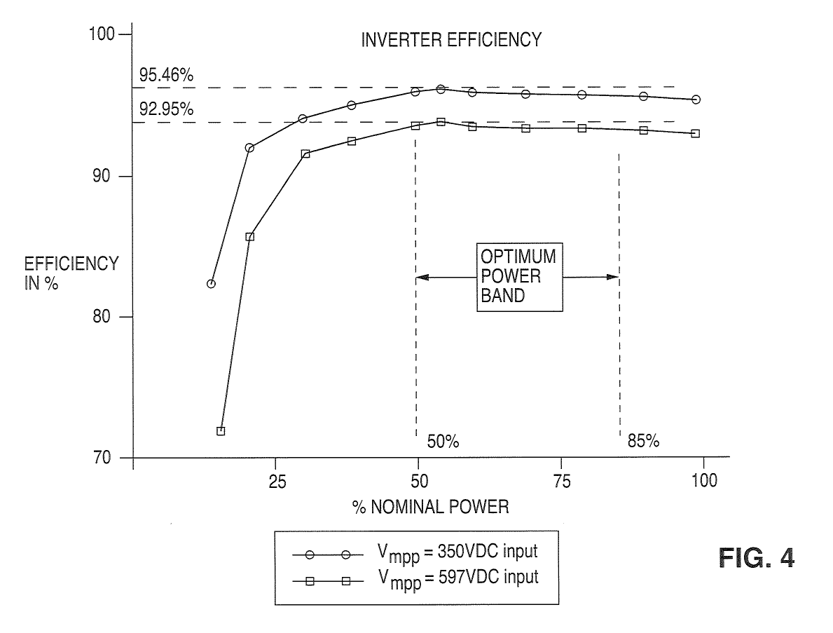

FIG. 4 illustrates an example graph for power conversion efficiency vs. percent (%) rated output power for DC to AC inverters operating with two input voltages according to embodiments of the present disclosure. The embodiment of the graph 400 shown in FIG. 4 is for illustration only. Other embodiments could be used without departing from the scope of this disclosure.

An example of the optimum power band for the inverters, referenced in FIG. 3, with three-hundred fifty Volts DC (350VDC) and five-ninety seven Volts DC (597VDC) input is shown in FIG. 4. Peak power conversion efficiency is at fifty-five percent (55%) of the rated maximum output power irrespective of the input voltage. Therefore, the optimum power band of fifty-percent (50%) to eighty-five (85%) rated maximum output power is determined by inverter rating and actual output power only.

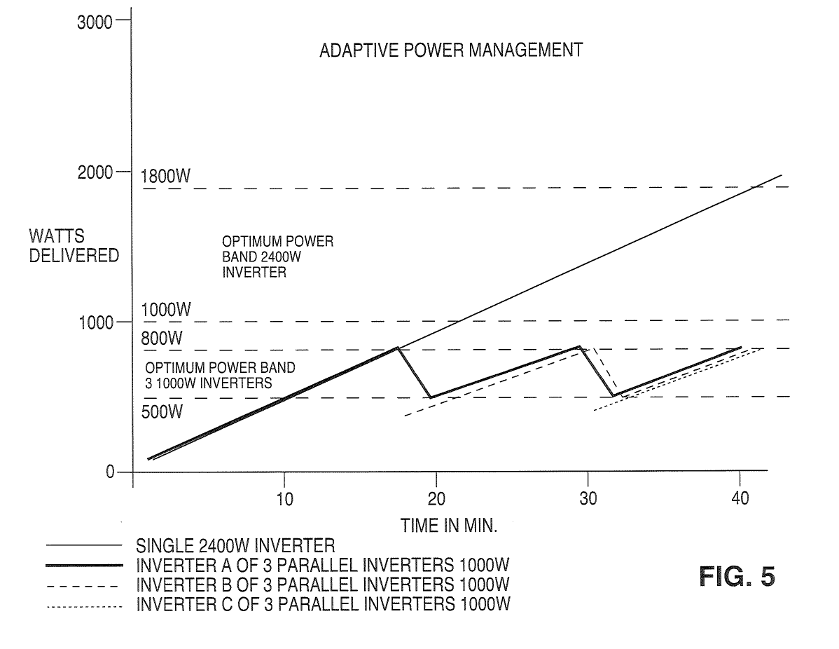

FIG. 5 illustrates an example graph for adaptive power management according to embodiments of the present disclosure. The embodiment of the graph 500 shown in FIG. 5 is for illustration only. Other embodiments could be used without departing from the scope of this disclosure.

The graph 500 shows a representation of the example of FIG. 2 wherein one (1) twenty-four hundred Watt (2400 W) rated inverter is compared with three (3) one-thousand Watt (1000 W) rated inverters. As power output increases to 2400 W for both inverter configurations, the single inverter moves into its optimum power band at 1000 W and moves out of its optimum power band at 1800 W. In the case of the three (3) 1000 W inverters, a first inverter goes into its optimum power band at 500 W and stays within its optimum power band as more inverters are enabled. The additional inverters add extra power to the output and at the same time all inverter outputs are maintained within the optimum power band.

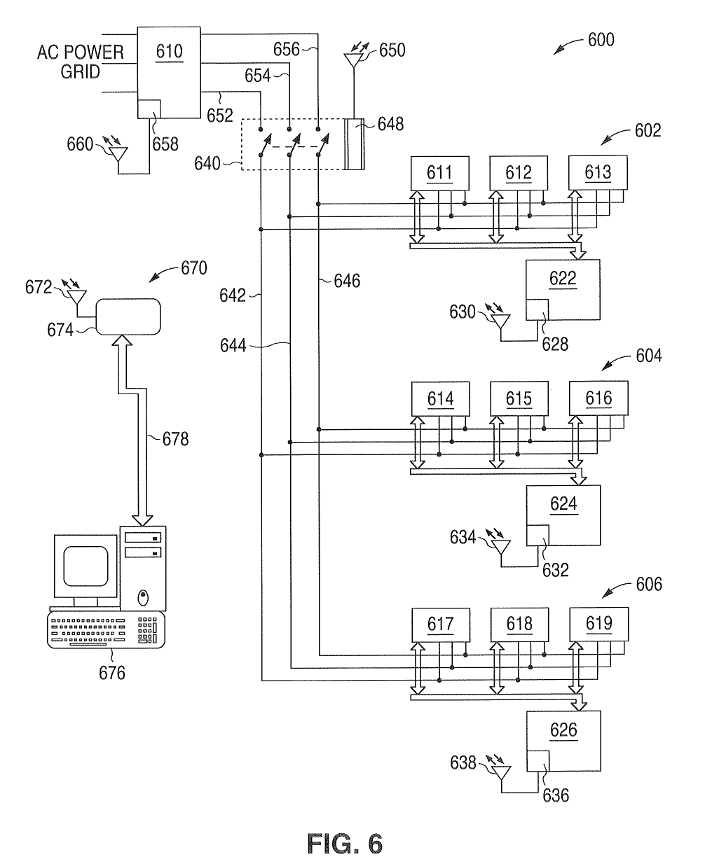

FIG. 6 illustrates a schematic diagram showing a solar array including groups of power inverters coupled to the electrical power grid through a single AC switching means responsive to a central controller facility according to embodiments of the present disclosure. The embodiment of the solar array 600 shown in FIG. 6 is for illustration only. Other embodiments could be used without departing from the scope of this disclosure.

The solar array 600 includes three groups 602, 604, 606 of power inverters. The three groups 602, 604, 606 are coupled in parallel. Accordingly, the output power from each group 602, 604, 606 is added together and transferred to the electrical power grid (or other AC electrical load) through an AC power demand meter 610.

Each group 602, 604, 606 includes three power inverters. The power inverters can be of the same structure and configuration as the power inverters 220 described herein above with respect to FIG. 2. It will be understood that illustration of three groups of power inverters including three power inverters each is for example purpose only and embodiments with different numbers of groups and different numbers of inverters per group could be used without departing from the scope of this disclosure.

The first group 602 of power inverters includes power inverters 611, 612, 613 and group controller 622. The second group 604 of power inverters includes power inverters 614, 615, 616 and group controller 624. The third group 606 of power inverters includes power inverters 617, 618, 619 and group controller 626. Additionally, each group controller 622, 624, 626 includes a data transceiver (e.g., also a transmitter and receiver in some embodiments). For example, group controller 622 includes data transceiver 628 coupled to antenna 630; group controller 624 includes data transceiver 632 coupled to antenna 634; and group controller 626 includes data transceiver 636 coupled to antenna 638.

The groups of inverters 602, 604, 606 are coupled by phase to a three phase switch 640. The groups of inverters 602, 604, 606 couple outputs A, B, and C from each inverter 611-619 to a corresponding switching component within the three phase switch 640. For example, a first output from inverters 611-619 is coupled via a first input line 642 to a first switching element in the three phase switch 640; a second output from inverters 611-619 is coupled via a second input line 644 to a second switching element in the three phase switch 640; and a third output from inverters 611-619 is coupled via a third input line 646 to a third switching element in the three phase switch 640. In some embodiments, the three phase switch 640 is three separate switches wherein each separate switch is coupled to a corresponding phase A, B, C from each of the groups 602, 604, 606. The three phase switch includes a transceiver 648 coupled to an antenna 650. The three phase switch 640 is operable to couple (e.g., connect and disconnect) input lines 642, 644, 646 to respective phase inputs 652, 654, 656 of the AC power demand meter 610. For example, the three phase switch 640 is configured to couple the first input line 642 to the phase input 652; couple the second input line 644 to the phase input 654; and couple the third input line 644 to the phase input 654.

AC power demand meter 610 includes output leads coupled to an electrical load such as, but not limited to, the electrical power distribution grid. AC power demand meter 610 measures line-to-line voltage across the output leads, which is the AC voltage of the electrical power grid. In additional and alternative embodiments, the AC power demand meter 610 measures the line-to-ground voltage at the output leads. The AC power demand meter 610 measures a total line current produced by the three groups of inverters 602, 604, 606 that are sending AC current through the phase inputs 652, 654, 656 of the AC power demand meter 610. In some embodiments, the AC power demand meter 610 transmits the measured voltage and output AC line currents via transceiver 658 and antenna 660 to a wireless data network 670.

The wireless data network 670 includes an antenna 672 coupled to a wireless router 674. The wireless data network 670 is in communication with a remote controller 676. In some embodiments, the remote controller 676 is coupled to the wireless data network 670 through the wireless router 674 via an internet or other wireline communication 678. In some embodiments, the wireless router 674 or antenna 672, or both, are included within the remote controller 676.

The remote controller 676 receives data via transceiver 674 and antenna 672. The data is received from group controllers 622, 624, 626. For example, group controller 622 transmits data via transceiver 628 and antenna 630 to remote controller 676 that receives the data via antenna 672 and wireless router 674.

The remote controller 676 also transmits commands via wireless router 674 and antenna 672. The commands are received by group controllers 622, 624, 626. For example, remote controller 676 transmits data via transceiver 674 and antenna 672 to group controller 622 that receives the data via antenna 630 and transceiver 628. Additionally, remote controller can transmit commands to the three phase switch 640. For example, the three phase switch 640 can receive commands from the remote controller 676 via antenna 650 and transceiver 648. In some embodiments, the remote controller 676 can transmit commands to the AC power demand meter 610, which receives the commands via antenna 660 and transceiver 658.

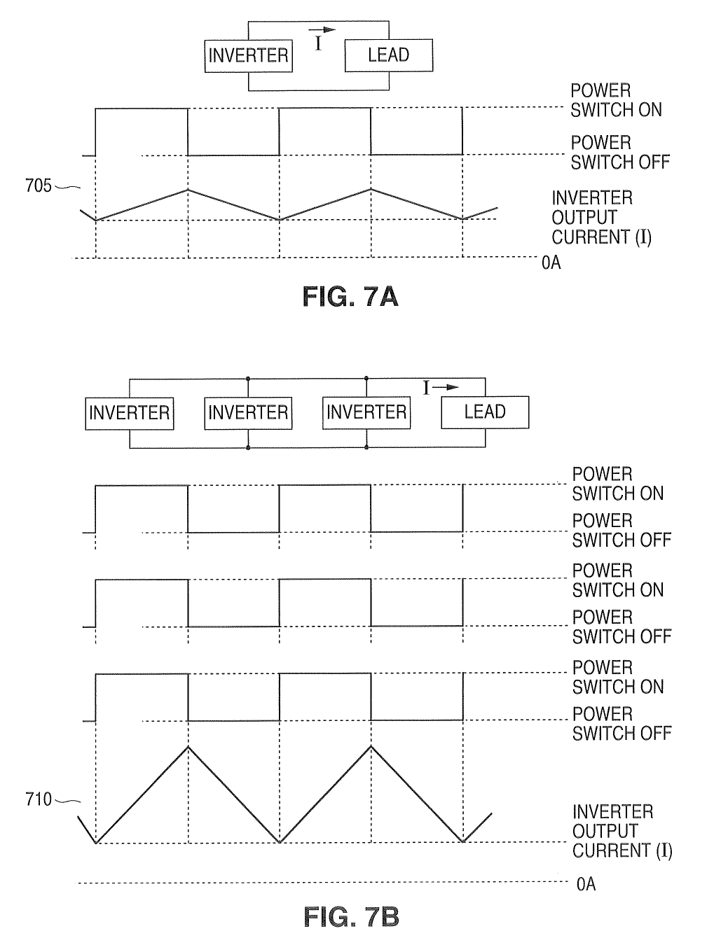

FIG. 7A illustrates example graph of the waveforms of the current ripple produced according to embodiments of the present disclosure. The embodiment of the graph shown in FIG. 7A is for illustration only. Other embodiments could be used without departing from the scope of this disclosure.

Wireless networking among all group controllers 622, 624, 626 and the remote controller 676 improves coordination of turn-ON times for every power inverter 611-619 in the solar array 600. When a power switch in a power inverter 611-619 turns on, output current starts increasing with a linear slope. When a power switch in a power inverter 611-619 turns off, output current starts decreasing with a linear slope. This switching creates a saw-tooth wave component 705 to the AC sine wave. The saw-tooth wave 705 has a fundamental frequency equal to the inverter power switch frequency and many harmonic frequencies of the fundamental frequency. When fundamental and harmonic frequencies are added to the AC sine wave, a harmonic distortion in the AC output is produced. When three power inverters are connected in parallel and their power switch turn-ON times and turn-OFF times are synchronized the amplitude of the saw-tooth wave component is tripled and the harmonic distortion is three times worse.

FIG. 7B illustrates an example graph of the current ripple of three synchronized inverters providing current to a load according to embodiments of the present disclosure. The embodiment of the graph shown in FIG. 73 is for illustration only. Other embodiments could be used without departing from the scope of this disclosure.

In an example, three power inverters are connected in parallel and their power switch turn-on times are spaced equally within one cycle time or one period of the inverter switching frequency. Then at any given time there are two inverters that are either building up or reducing output current while the third one is doing the opposite to the output current. This means that at any time the ripple in the output current is either rising or falling at the same rate as for one inverter but rises or falls for one third of the time that it does for a single inverter. The result is a saw-tooth wave 710 form of ripple current that is three times the inverter switching frequency but one third the amplitude of ripple current 705 for a single inverter. The amplitude of harmonics of the fundamental frequency of the ripple current is also one third of what they would be for a single inverter.

FIG. 7C illustrates an example graph of the current for three coordinated interleaved inverters providing current to a load according to embodiments of the present disclosure. The embodiment of the graph shown in FIG. 7C is for illustration only. Other embodiments could be used without departing from the scope of this disclosure.

In some embodiments, the inverters are interleaved per phase. In such embodiments, one inverter is turned ON prior to a second inverter. Further a third inverter is turned ON at a time subsequent to the second inverter. The intervals between when each inverter is turned ON can be based on the number of inverters that are being switched ON and off. For example, the interval can be a phase shift between negative twenty degrees (−20°) to positive twenty degrees (+20°). Coordinated interleaving works in conjunction with maximum power point calculation synchronization to reduce harmonics in the AC output sent to the AC power grid. Coordinated interleaving provides destructive interference of the frequencies from each inverter rather than constructive interference illustrated by the saw-tooth wave 710 form in FIG. 7B. Therefore, the saw-tooth wave 715 form created by the interleaved inverters is significantly smaller than that of the synchronized inverters illustrated in FIG. 7B and, in some embodiments, smaller than the saw-tooth ripple current 705 of the single inverter illustrated in FIG. 7A.

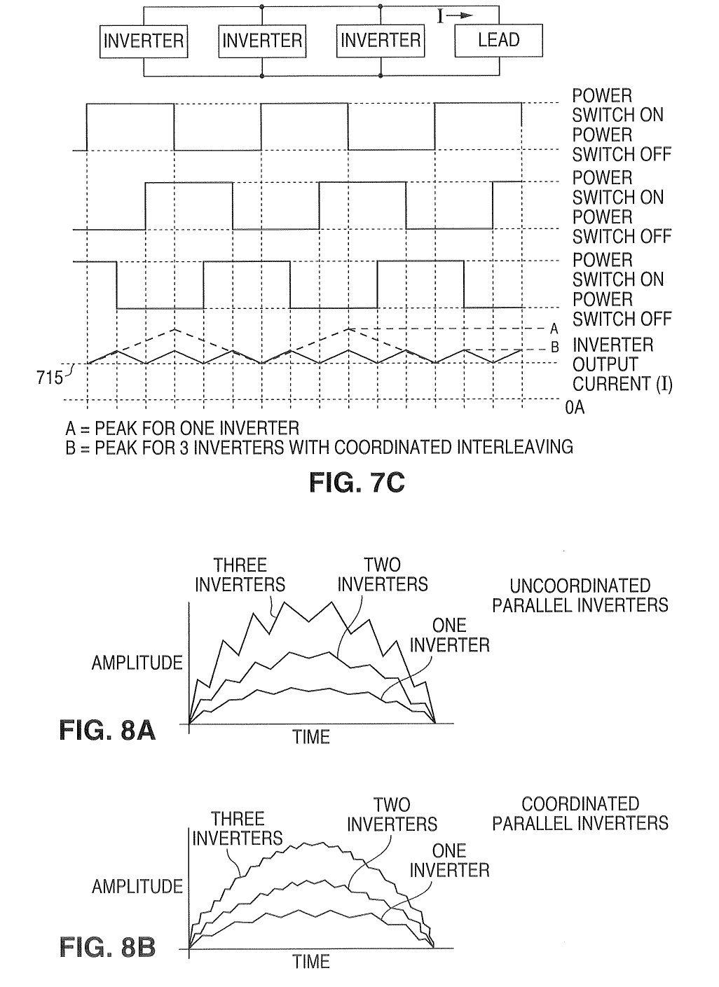

FIG. 8 illustrates example graphs showing the effects of uncoordinated and coordinated interleaved inverters on harmonic distortion of output sine waves according to embodiments of the present disclosure. The embodiments of the graphs shown in FIG. 8 are for illustration only. Other embodiments could be used without departing from the scope of this disclosure.

The graphical representation shown in FIG. 8 compares the effects of uncoordinated inverters with coordinated interleaved inverters on harmonic content of an AC sine wave. The top graph shows a half sine wave of output current for two and three parallel coupled, uncoordinated inverters. The top graph illustrates that the amplitude of the saw-tooth current ripple added to the sine wave gets progressively larger in amplitude when going from one inverter to two inverters in parallel to three inverters in parallel.

The bottom graph shows a half sine wave of output current for two and three parallel coupled, coordinated interleaved inverters. It will be understood that illustration of only two and three parallel coupled coordinated interleaved inverters is for example purposes only and more than three inverters could be used without departing from the scope of this disclosure. In the case of the coordinated interleaved inverters, the amplitude of the saw-tooth current ripple added to the sine wave gets progressively higher in frequency and less in amplitude when going from one inverter to two inverters in parallel to three inverters in parallel.

Coordinated interleaving can be extended to four or more inverters coupled in parallel. For coordinated interleaving, only one inverter power switch in one of N parallel-connected inverters transitions from the OFF state to the ON state, or transitions from the ON state to the OFF state, at any instant. The transitions from OFF state to ON state of consecutive power switch activations (turning on) is the period of the inverter switching frequency divided by N.

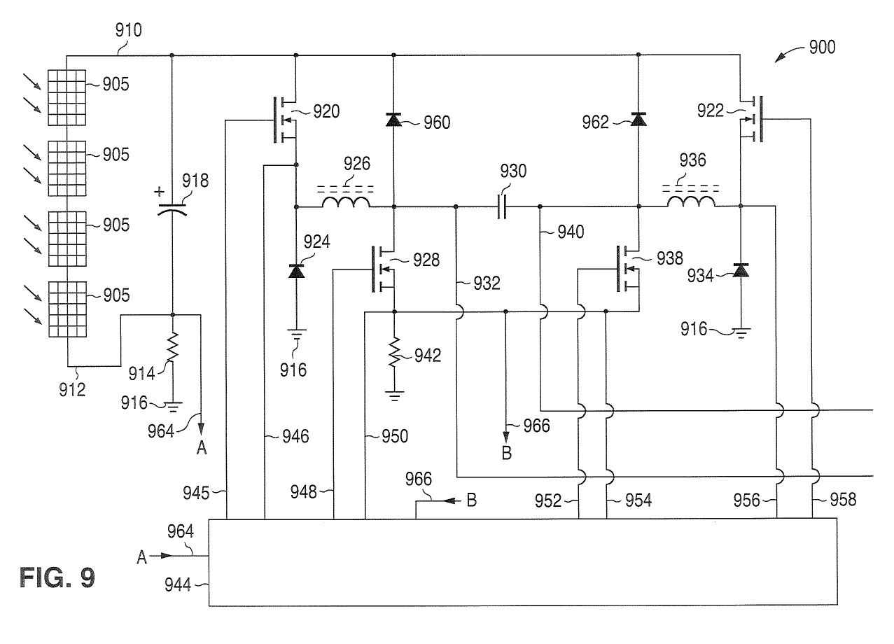

FIG. 9 illustrates a schematic diagram for a transformer-less, no boost DC to AC power inverter according to embodiments of the present disclosure. The embodiment of the inverter shown in FIG. 9 is for illustration only. Other embodiments could be used without departing from the scope of this disclosure.

In some embodiments, the inverter 900 is capable of generating an AC output from a DC input without a DC voltage boost. Therefore, the inverter 900 provides an advantage in terms of efficiency over conventional DC to AC power converters because inverter 900 only includes a switching conversion stage.

In some such embodiments, the power switches and current limiting inductors are connected together inside the inverters 220. The solar array includes a number of solar panels 905. The solar panels 905 can be of the same structure and configuration as the solar panels 105 described herein above with respect to FIG. 1.

The inverter 900 includes a positive (+) DC power input line 910 and a negative (−) DC power input line 912. An input current sense resistor 914 is coupled between the negative DC power input line 912 and ground 916. A noise filter capacitor 918 is coupled between the positive DC input power line 910 and the negative DC power input line 912. The positive DC input power line 910 further is coupled to a drain nodes of a high side power switch 920 and high side power switch 922 such that the positive lead of capacitor 918 also is coupled to the drain nodes of the high side power switches 920, 922. The source of power switch 920 is coupled to the cathode of a first freewheel diode 924 and a first lead of a first current limiting inductor 926. The anode of the first freewheel diode 924 is coupled to ground 916. The second lead of the first current limiting inductor 926 is coupled to the drain of a first pull down switch 928, a first lead of output noise filter capacitor 930, and an AC output ‘L’ line 932. The source of power switch 922 is coupled to the cathode of a second freewheel diode 934 and a first lead of a second current limiting inductor 936. The anode of the second freewheel diode 934 is coupled to ground 916. The second lead of the second current limiting inductor 936 is coupled to the drain of a second pull down switch 938, a second lead of output noise filter capacitor 930, and AC output ‘N’ line 940. The source nodes of the pull down switches 928, 938 are coupled to each other and to an isolated power ground through output current sense resistor 942. The inverter 900 includes an inverter controller 944 that communicates first control signals to switch 920 on control lines 945 and 946, second control signals to switch 928 on control lines 948 and 950, third control signals to switch 938 on control lines 952 and 954, and fourth control signals to switch 922 on control lines 956 and 958.

The inverter 900 operates during the positive half cycle of an AC sine wave output by controller 944 first applying a positive voltage on line 952 relative to line 954 to turn ON switch 938; then applying a pulse width modulated square wave that varies between zero volts and a positive voltage on line 945 relative to line 946 to turn power switch 9200N and OFF alternately with a constantly changing ON time and a constantly changing OFF time.

The constantly changing ON times and OFF times of power switch 920 causes output current in the inductors 926, 936 to build up or decay by varying amounts over one ON-OFF cycle of power switch 920 such that the average output current follows the shape of a positive half sine wave over time. Pull down switch 938 stays ON for the entire time of the positive half sine wave and is turned OFF simultaneously with the turn ON of pull down switch 928. The negative half of the AC sine wave is produced in exactly the same way as the positive half except switch 928 is turned ON for the entire time of the negative half sine wave by a positive voltage applied to line 948 relative to line 950. Power switch 922 is then turned ON and OFF alternately by a pulse width modulated square wave voltage on control lines 958 and 956 to cause the output current to follow the shape of a negative half sine wave (output current direction is reversed).

The anode of a first clamp diode 960 is coupled to the drain of switch 928. The cathode of the first clamp diode 960 is coupled to the positive DC power input line 910. The anode of a second clamp diode 962 is coupled to the drain of switch 938 and the cathode of the second clamp diode 962 is coupled to the positive DC power input line 910.

Voltage across input sense resistor 914 is representative of input current and is coupled to controller 944 by line 964. Voltage across output sense resistor 942 is representative of output current and is coupled to controller 944 by line 966.

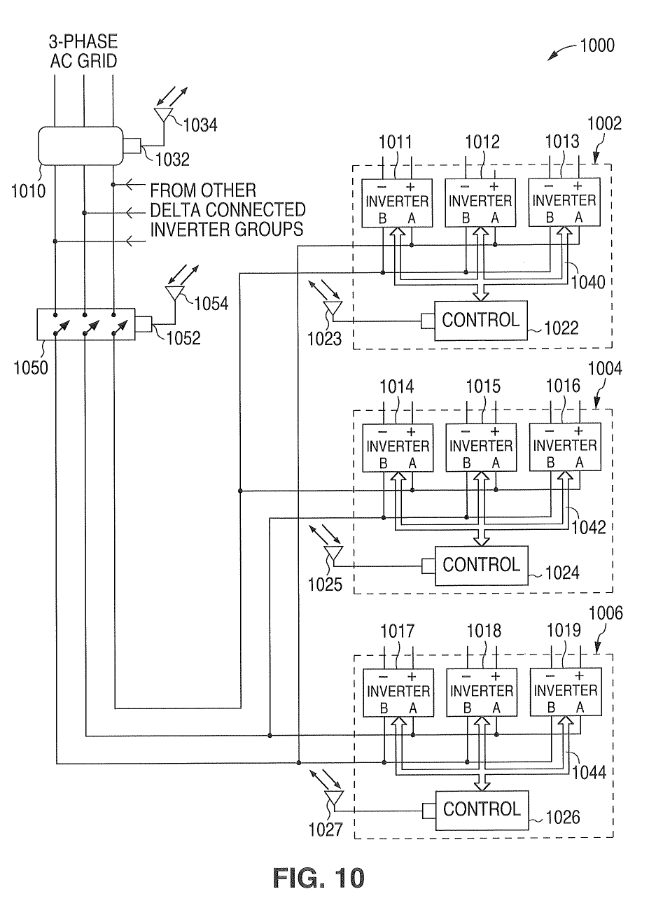

FIG. 10 illustrates is a schematic diagram for a solar array with inverter groups coupled in a three-phase delta configuration for 3-phase AC power generation according to embodiments of the present disclosure. The embodiment of the solar array shown in FIG. 10 is for illustration only. Other embodiments could be used without departing from the scope of this disclosure.

In some embodiments, an additional coordinating process is performed by the wireless data network when the groups of inverters 1002, 1004, 1006 are coupled in a three-phase delta configuration. The wireless data network, including the remote controller (discussed in further detail herein above with respect to FIG. 6) group controllers 1022, 1024, 1026 perform adaptive power factor and phase balancing.

Adaptive power factor and phase balancing operates as follows. In the event that AC output meter 1010 for the entire installation (e.g. the solar site) detects an excessive voltage sine wave timing shift of one phase relative to the sine waves of the other phases or detects an excessive sine wave timing shift between voltage and current on one phase, the AC output meter 1010 transmits information about this problem over the wireless network via wireless transceiver 1032 and antenna 1034 to all group controllers 1022, 1024, 1026. Group controllers include a transceiver and antenna for receiving and transmitting information. For example, Group controller 1022 includes transceiver and antenna 1023; Group controller 1024 includes transceiver and antenna 1025; and Group controller 1027. Group controllers 1022, 1024, 1026 then signal their respective inverters 1011-1019 via LAN connections 1040, 1042 and 1044 respectively to bring the sine wave timing of all phases back into normal three phase timing.

Finally the LAN connections 1040, 1042 and 1044 of the inverter groups 1002, 1004, 1006, the wireless data network and the wireless router with internet (or other data wireline) connection enable the data collected by solar panel sensors, power inverters 1011-1019 and the AC meter 1010 to be transferred to the remote controller for analyzing the function of the solar array installation and for alerting system operators about problems and failures at the installation. If any inverter 1011-1019 in an inverter group 1002, 1004, 1006 fails, the group controller 1022, 1024, 1026 shuts that inverter down, without affecting the others. Thereafter, the remaining inverters take over the load. The group controller 1022, 1024, 1026 then sends an alert via the wireless data network, the wireless router and the Internet to the remote controller to inform system operators about the failure.

Additionally and alternatively, in the event that any inverter 1011-1019 in an inverter group 1002, 1004, 1006 has internal temperatures above a threshold value, that inverter goes into an output power limit mode and the other inverters in the group produce more power to make up for any lost power. The group controller 1022, 1024, 1026 also sends an alert to the remote controller for this condition as well.

In additional and alternative embodiments, the DC to AC inverter includes a controller configured to perform an internal efficiency optimization method known as variable frequency switching of the inverter power switches. The controller is able to perform the variable frequency switching independent of other previously described optimization methods that require data links between inverters to coordinate inverter operation. The inverter power switch frequency, also known as the switching frequency, is typically set around 20 khz. If the switching frequency goes higher than 20 khz, smaller components can be used because the power transferred in each PWM cycle is smaller. Smaller components result in lower product costs. However as the switching frequency goes up, the switching losses also increase and power conversion efficiency goes down. Alternatively, as the switching frequency goes down the switching losses go down and power conversion efficiency goes up.

In yet additional and alternative embodiments, the inverters are configured to maintain operations in a Continuous Conduction Mode (CCM). Inverters operate in two operating modes: CCM and Dis-continuous Conduction Modes (DCM). In CCM the inductor current never reaches 0. In DCM the inductor current reaches 0. For efficient operation the inverter is configured to operate only in the CCM mode. The primary control in the inverters to reduce switching losses during peak output power intervals of the sine wave, while maintaining operation in the CCM mode, is the adjustment of the switching frequency in response to varying voltage and current. Thus, as the output voltage and power approach maximum in the sinusoidal signal, the switching frequency is adjusted downward to minimize switching losses during maximum power transfer. Then as the sinusoidal output approaches a low output voltage and power, the switching frequency can be increased to a higher frequency such that the current through the inductor does not decrease to zero.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. An energy conversion array for use in an energy generating system, the array comprising:
a plurality of inverters adapted to receive a direct current energy and output an alternating current energy, wherein an output of a first inverter is interleaved with an output of a second inverter.

2. The array as set forth in claim 1, wherein the plurality of inverters is adapted to couple to at least one of a solar energy generating system, wind energy generation system, geothermal energy generation system, and a water based energy generating system.

3. An energy conversion array for use in an energy generating system, the array comprising:
a plurality of intelligent inverters adapted to receive a direct current energy and output an alternating current energy, the plurality of inverters configured to perform power band optimization.

4. The array as set forth in claim 3, further comprising a plurality of sensors configured to measure a value from of each of a plurality of energy generating devices, said value corresponding to at least one of temperature, output current and output voltage.

5. The array as set forth in claim 4, further comprising a group controller coupled to a number of the plurality of inverters, wherein the group controller is configured to use the value received from the plurality of sensors to vary an operation of at least one of the plurality of inverters.

6. The array as set forth in claim 5, wherein the group controller is configured to transmit data to a remote controller and is responsive to commands received from said remote controller.

7. The array as set forth in claim 3, further comprising a group controller configured to:
measure a power output of the plurality of inverters;
compare the measured power to at least one of an upper limit of an optimum power band and a lower limit of the optimum power band;
enable at least one additional inverter in response to a determination that the measured power exceeds the upper limit; and
disable at least one inverter in response to a determination that the measured power is lower than the lower limit.

8. An energy conversion array for use in an energy generating system, the array comprising:
a plurality of solar power generating devices; and
a plurality of inverters, each of the plurality of inverters adapted to receive a direct current energy from one of the plurality of solar power generating devices and output an alternating current energy, wherein an output of a first inverter is interleaved with an output of a second inverter.

9. The array as set forth in claim 8, wherein each of the plurality of solar power generating devices comprises one of a solar panel, a string of solar panels, and a plurality of strings of solar panels coupled in parallel.

10. An energy conversion array for use in a solar power system, the array comprising:
a plurality of solar power generating devices; and
a plurality of inverters coupled to the plurality of power generating devices, the plurality of inverters configured to receive a non-regulated direct current energy and coordinate an output of an alternating current energy.

11. The array as set forth in claim 10, further comprising a plurality of controllers coupled to the plurality of inverters.

12. The array as set forth in claim 11, wherein the plurality of controllers are configured to communicate via a local area network connection.

13. The array as set forth in claim 11, wherein the plurality of controllers are configured to transmit data to a remote controller.

14. The array as set forth in claim 10, wherein the plurality of controllers are configured to:
measure a power output of the plurality of inverters;
compare the measured power to at least one of an upper limit of an optimum power band and a lower limit of the optimum power band;
enable at least one additional inverter in response to a determination that the measured power exceeds the upper limit; and
disable at least one inverter in response to a determination that the measured power is lower than the lower limit.

15. The array as set forth in claim 10, wherein the plurality of inverters are configured to perform a power optimization of the alternating current energy.

16. The array as set forth in claim 10, wherein the plurality of inverters are configured to interleave outputs of the alternating current energy.

17. The array as set forth in claim 10, wherein the solar power generating device is one of a solar panel, a string of solar panels, and a plurality of strings of solar panels coupled in parallel.

18. A method for current conversion for a power array, the method comprising:
receiving, by a plurality of inverters, electrical energy from a plurality of energy generation devices;
coordinating a switching of the plurality of inverters to perform a conversion of a direct current energy to an alternating current energy by the plurality of inverters.

19. The method set forth in claim 18, measuring a value corresponding to at least one of input current, input voltage, output current, output voltage, solar panel temperature, and solar array temperature.

20. The method as set forth in claim 19, wherein coordinating further comprises varying an operation of the plurality of inverters based on the measured value.

21. The method as set forth in claim 18, further comprising receiving data from at least one of a power demand meter and a controller of a different plurality of inverters, wherein the data includes measurements of at least one of a voltage, a current, and a temperature for at least one solar panel.

22. The method as set forth in claim 21, wherein coordinating further comprises varying an operation of the plurality of inverters based on the received data.

23. The method as set forth in claim 18, further comprising transmitting data to at least one of a remote controller and a second controller of a different plurality of inverters, wherein the data includes measurements of at least one of a voltage, a current, and a temperature for at least one solar panel.

24. The method as set forth in claim 18, wherein coordinating comprises:
measuring a power output of the plurality of inverters;
comparing the measured power to at least one of an upper limit of an optimum power band and a lower limit of the optimum power band;
enabling at least one additional inverter in response to a determination that the measured power exceeds the upper limit; and
disabling at least one inverter in response to a determination that the measured power is lower than the lower limit.
